(19) United States
(12) Patent Application Publication
(10) Pub. No.: US 2009/0039436 A1
(43) Pub. Date: Feb. 12, 2009

(54) High Performance Metal Gate CMOS with High-K Gate Dielectric

(76) Inventors: Bruce B. Doris, Brewster, NY (US); Eduard Albert Cartier, New York, NY (US); Barry Paul Linder, Hastings-on-Hudson, NY (US); Vijay Narayanan, New York, NY (US); Vamsi Paruchuri, New York, NY (US); Mark Todhunter Robson, Danbury, CT (US); Michelle L. Steen, Danbury, CT (US); Ying Zhang, Yorktown Heights, NY (US)

Correspondence Address: INNOVATION INTERFACE, LLC, 303 TABER AVENUE, PROVIDENCE, RI, 02906, US

(21) Appl. No.: 11/835,320

(22) Filed: Aug. 7, 2007

(51) Int. Cl. H01L 29/78; H01L 21/8238

(52) U.S. Cl. 257/369; 438/199; 257/E29.255; 257/E21.632

(57) ABSTRACT

A CMOS structure is disclosed in which both type of FET devices have gate insulators containing high-k dielectrics, and gates containing metals. The threshold of the two type of devices are adjusted in separate manners. One type of device has its threshold set by exposing the high-k dielectric to oxygen. During the oxygen exposure the other type of device is covered by a stressing dielectric layer, which layer also prevents oxygen penetration to its high-k gate dielectric. The high performance of the CMOS structure is further enhanced by adjusting the effective workfunctions of the gates to near band-edge values both NFET and PFET devices.

### FIELD OF THE INVENTION

The present invention relates to electronic devices. In particular, it relates to CMOS structures having high-k containing gate dielectrics and metal containing gates. The invention also relates to ways of adjusting the threshold voltages for suiting high performance operation.

### BACKGROUND OF THE INVENTION

Today's integrated circuits include a vast number of devices. Smaller devices and shrinking ground rules are the key to enhance performance and to reduce cost. As FET (Field-Effect-Transistor) devices are being scaled down, the technology becomes more complex, and changes in device structures and new fabrication methods are needed to maintain the expected performance enhancement from one generation of devices to the next. The mainstay material of microelectronics is silicon (Si), or more broadly, Si based materials. Among others, one such Si based material of importance for microelectronics is the silicon-germanium (SiGe) alloy. The devices in the embodiments of the present disclosure are typically part of the art of Si based material device technology.

There is a great difficulty in maintaining performance improvements in devices of deeply submicron generations. Therefore, methods for improving performance without scaling down have become of interest. There is a promising avenue toward higher gate capacitance without having to make the gate dielectric actually thinner. This approach involves the use of so called high-k materials. The dielectric constant of such materials is significantly higher than that of SiO₂, which is about 3.9. A high-k material may physically be significantly thicker than an oxide, and still have a lower equivalent oxide thickness (EOT) value. The EOT, a concept known in the art, refers to the thickness of such an SiO₂ layer which has the same capacitance per unit area as the insulator layer in question. In today state of the art FET devices, one is aiming at an EOT of below 2 nm, and preferably below 1 nm.

Device performance is also enhanced by the use of metal gates. The depletion region in the poly-Si next to the gate insulator can become an obstacle in increasing gate-to-channel capacitance. The solution is to use a metal gate. Metal gates also assure good conductivity along the width direction of the devices, reducing the danger of possible RC delays in the gate.

High performance small FET devices are in need of precise threshold voltage control. As operating voltage decreases, to 2V and lower, threshold voltages also have to decrease, and threshold variation becomes less tolerable. Every new element, such as a different gate dielectric, or a different gate material, influences the threshold voltage. Sometimes such influences are detrimental for achieving the desired threshold voltage values. Any technique which can affect the threshold voltage, without other effects on the devices is a useful one. One such technique, available when high-k dielectrics are present in a gate insulator, is the exposure of the gate dielectric to oxygen. A high-k material upon exposure to oxygen lowers the PFET threshold and increases the NFET threshold. Such an effect has already been reported, for instance: “2005 Symposium on VLSI Technology Digest of Technical Papers, Pg. 230, by E. Cartier”. Unfortunately, shifting the threshold of both PFET and NFET devices simultaneously, may not easily lead to threshold values in an acceptable tight range for CMOS circuits. There is great need for a structure and a technique in which the threshold of one type of device can be adjusted without altering the threshold of the other type of device.

In enhancing FET performance a general approach is to stress tensilely or compressively the device channels. One prefers to have NFET device channel to be tensilely stressed, while the PFET device channel to be compressively stressed. It would be desirably combine the threshold adjusting features of the high-k dielectric and metal gate with the stressing of the device channels. To date, such a structure, and a technique for its fabrication has not been taught.

### SUMMARY OF THE INVENTION

In view of the discussed difficulties, embodiments of the present invention discloses a CMOS structure which contains at least one first type FET device, and at least one second type FET device. The first type FET device includes a first channel hosted in a Si based material, a first gate which contains a first metal and may also have a cap layer, a first gate insulator which contains a first high-k dielectric, which first high-k dielectric may directly be contacting the cap layer. The first type FET device also has a first dielectric layer overlaying the first gate and at least portions of the vicinity of the first gate. The first dielectric layer and the first channel are in a first state of stress, the first state of stress being imparted by the first dielectric layer onto the first channel. The second type FET device contains a second channel hosted in the Si based material, a second gate, which includes a second metal, and a second gate insulator having a second high-k dielectric. The second high-k dielectric is in direct contact with the second metal. The second type FET device also has a second dielectric layer overlaying the second gate and at least portions of the vicinity of the second gate. The second dielectric layer and the second channel are in a second state of stress, the second state of stress being imparted by the second dielectric layer onto the second channel. The absolute values of the saturation thresholds of the first and the second FET devices are less than about 0.4 V.

Embodiments of the present invention further discloses a method for producing a CMOS structure. The method includes the fabrication of a first type FET device by implementing a first gate insulator including a first high-k dielectric, and a first channel in a Si based material underlying the first gate insulator. The fabrication of the first type FET device further includes the implementation of a first gate including a first metal. The first gate and at least portions of the vicinity of the first gate are overlaid with a first dielectric layer, which is in a first state of stress. The first dielectric layer imparts the first state of stress onto the first channel. The method also includes the fabrication of a second type FET device by implementing a second gate insulator including a second high-k dielectric, and a second channel in the Si based material underlying the second gate insulator. The fabrication of the second type FET device further includes the implementation of a second gate including a second metal. The second high-k dielectric being in direct contact with the second metal. The method further includes exposing the first type FET device and the second type FET device to oxygen. The oxygen reaches the second high-k dielectric of the second gate insulator, and adjusts the threshold voltage of the second type FET device in such manner that the absolute value of its saturation threshold is less than about 0.4 V. In the meantime, due to the first dielectric layer, oxygen is prevented from reaching the first high-k dielectric of the first gate insulator, and the threshold voltage of the first type FET device stays unchanged, such that the absolute value of its saturation threshold is also less than about 0.4 V.

### BRIEF DESCRIPTION OF THE DRAWINGS

These and other features of the present invention will become apparent from the accompanying detailed description and drawings, wherein:

FIG. 1 shows a schematic cross section of a CMOS structure according to an embodiment of the present invention including compressive and tensile dielectric layers, metal containing gates, and high-k dielectrics;

FIG. 2 shows a schematic cross section of an initial state of the processing for embodiments of the present invention;

FIG. 3 shows a schematic cross section of a following stage in the processing of embodiments of the present invention where the spacers have been removed;

FIG. 4 shows a schematic cross section of a stage in the processing of embodiments of the present invention where a stressed and oxygen blocking dielectric layer has been deposited, and the structure is exposed to oxygen; and

FIG. 5 shows a symbolic view of a processor containing at least one CMOS circuit according to an embodiment of the present invention.

### DETAILED DESCRIPTION OF THE INVENTION

It is understood that Field Effect Transistor-s (FET) are well known in the electronic arts. Standard components of a FET are the source, the drain, the body in-between the source and the drain, and the gate. The body is usually part of a substrate, and it is often called substrate. The gate is overlaying the body and is capable to induce a conducting channel in the body between the source and the drain. In the usual nomenclature, the channel is hosted by the body. The gate is separated from the body by the gate insulator. There are two type of FET devices: a hole conduction type, called PFET, and an electron conduction type, called NFET. Often PFET and NFET devices are wired into CMOS circuits. A CMOS circuit contains at least one PFET and at least one NFET device. In manufacturing, or processing, when NFET and PFET devices are fabricated together on the same chip, one is dealing with CMOS processing and the fabrication of CMOS structures.

In FET operation an inherent electrical attribute is the threshold voltage. When the voltage between the source and the gate exceeds the threshold voltage, the FETs are capable to carry current between the source and the drain. Since the threshold is a voltage difference between the source and the gate of the device, in general NFET threshold voltages are positive values, and PFET threshold voltages are negative values. Typically, two threshold voltages are considered in the electronic art: the low voltage threshold, and the saturation threshold. The saturation threshold, which is the threshold voltage when a high voltage is applied between the source and the drain, is lower than the low voltage threshold. Usually, at any given point in the technology's miniaturization, higher performance devices have lower thresholds than the, possibly more power conscious, lower performance devices.

As FET devices are scaled to smaller size, the traditional way of setting threshold voltage, namely by adjusting body and channel doping, loses effectiveness. The effective workfunction of the gate material, and the gate insulator properties are becoming important factors in determining the thresholds of small FETs. Such, so called small, FETs have typically gate, or gate stack, lengths less than 50 nm, and operate in the range of less than about 1.5 V. The gate stack, or gate, length is defined in the direction of the device current flow, between the source and the drain. For small FETs the technology is progressing toward the use of metallic gates and high-k dielectric for gate insulators. However, the optimal combination from a performance, or processing point of view, of a particular metal gate, and a particular high-k dielectric in the gate insulator, might not lead to optimal threshold values for both NFET and PFET devices.

It is know that exposing a gate dielectric which comprises a high-k material to oxygen, can result in shifting device thresholds in a direction which is the same as if one moved the gate workfunction toward the p⁺ silicon workfunction. This results in lowering the PFET threshold, namely, making it a smaller negative voltage, and raising the NFET threshold, namely making it a larger positive voltage. It is preferable to carry out such an oxygen exposure at relatively low temperatures, and it is also preferable that no high temperature processing should occur afterwards. Accordingly, such a threshold shifting operation should occur late in the device fabrication, typically after the source and the drain have been activated. This requirement means that one has to expose the high-k material in the gate dielectric at a point in the fabrication process when substantially most of the processing has already been carried out, for instance, the gate, and gate sidewalls are all in place, and the gate insulator is shielded under possibly several layers of various materials. However, there may be a path for the oxygen to reach from the environs to the gate insulator. This path is through oxide, SiO₂, based materials, or directly and laterally through the high-k material itself. Oxide typically is the material of liners. Liners are thin insulating layers which are deposited conformally essentially over all of the structures, in particular over the gates and the source/drain regions. Use of liners is standard practice in CMOS processing. From the point of view of adjusting the threshold of the device, the property of interest is that the liner would be penetrable by oxygen. Indeed, as referenced earlier, such threshold shifts due to oxygen diffusion through liners, are known in the art. Additional layers that may separate a gate insulator from the environment after the source and the drain have already been fabricated, are so called offset spacers. As known in the art, offset spacers are usually on the side of the gate, fulfilling the same role for source/drain extension and halo implants, as the regular spacers fulfill in respect to the deeper portions of the source/drain junctions. Offset spacers may typically also be fabricated from oxide. Consequently, if a FET is exposed to oxygen, when a liner and an offset spacer are covering the gate, the oxygen may reach the gate insulator within a short time, measured in minutes our hours. However, in any given particular embodiment of FET fabrication there may be further layers, or fewer layers, covering the gate after the source/drain fabrication, but as long as they do not block oxygen, they are not forming an obstacle to adjusting the threshold by oxygen exposure.

It would be preferable if the thresholds of the different types of devices could be adjusted individually, meaning, one would desire to use threshold tuning techniques, such as the oxygen exposure, in a manner that the threshold of one type device becomes shifted without affecting the threshold of the other type of device. Embodiments of the present invention teach such a selective adjusting of a device threshold by having oxygen diffusing to the gate dielectric of one type of FET, while the other type of FET is not affected. The device not to be affected by the oxygen exposure is covered by a dielectric layer which does not permit oxygen penetration. Such an oxygen blocking dielectric layer may be of nitride (SiN). In embodiments of the present invention the nitride layer is not only used to block oxygen, but it is deposited in such conditions that it is in a stressed state, and it imparts this stressed state onto the channel of the FET. This stress in the channel results in higher device performance. After the oxygen exposure, the device with the changed threshold also receives an appropriately stressed dielectric layer mainly in order to improve its performance.

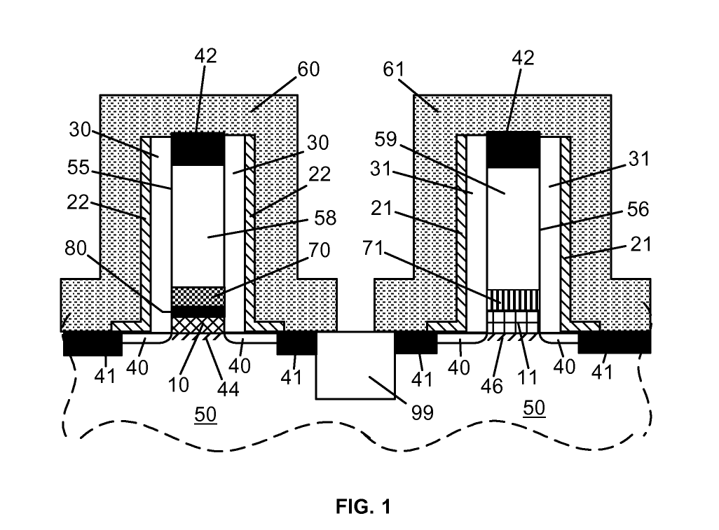

FIG. 1 shows a schematic cross section of a CMOS structure according to an embodiment of the present invention, including compressive and tensile dielectric layers, metal containing gates, high-k dielectrics, and thresholds adapted for high performance. Furthermore, the structure as depicted has already been exposed to oxygen, and has the thresholds of both devices optimized.

FIG. 1 depicts two devices, an NFET and a PFET, of the at least one NFET and PFET device that make up a CMOS structure. In FIG. 1, and in the following figures, it is not specified which one of the two devices is an NFET and which one is a PFET. Embodiments of the invention cover both cases, as to which type of device, NFET or PFET, is the one whose threshold is adjusted by oxygen exposure. Accordingly, a first type and a second type device will be discussed, with the understanding that if the first type is an NFET then the second type is a PFET, and the other way around, if the first type is a PFET then the second type is an NFET.

It is understood that in addition to the elements of the embodiments of the invention the figures show several other elements, since they are standard components of FET devices. The device bodies 50 are of a Si based material, typically of single crystal. In a representative embodiment of the invention the Si based material bodies 50 are essentially of Si. In exemplary embodiments of the invention the device bodies 50 are part of a substrate. The substrate may be any type known in the electronic art, such as bulk, or semiconductor on insulator (SOI), fully depleted, or partially depleted, FIN type, or any other kind. Also, substrates may have various wells of various conductivity types, in various nested positioning enclosing device bodies. The figure shows what typically may be only a small fraction of an electronic chip, for instance a processor, as indicated by the wavy dashed line boundaries. The devices may be isolated from one another by any method known in the art. The figure shows a shallow trench 99 isolation scheme, as this is a typical advanced isolation technique available in the art. The devices have source/drain extensions 40, and silicided sources and drains 41, as well as have silicide 42 as top of the gate stacks 55, 56. As one skilled in the art would know, these elements all have their individual characteristics. Accordingly, when common indicators numbers are used in the figures of the present disclosure, it is because from the point of view of embodiments of the present invention the individual characteristics of such elements are of no major importance. FIG. 1 shows the devices at a stage when the fabrication of the sources and drains have essentially already been completed.

The devices have standard sidewall offset spacers 30, 31. For embodiments of the present invention the offset spacer material is of significance only to the extent that the offset spacer 31 pertaining to the second type FET device, the one which had its threshold adjusted by oxygen exposure, is preferably penetrable by oxygen. The typical material used in the art for such spacers is oxide. Typically the spacer of the first type FET device 30 and the spacer of the second type FET device 31 are fabricated during the same processing steps, and are of the same material. However, for representative embodiments of the present invention the offset spacers 30, 31 are not essential, and may not be employed at all, or may be removed before the structures are finalized. In addition, there may be protective layers to prevent oxygen penetration during standard processing, such as, for instance, photo-resist removal.

The devices show liners 22, 21 as known in the art. Such liners are regularly used in standard CMOS processing. The material of such liners is usually an oxide, typically silicon-dioxide (SiO₂), but in some cases it may be nitride (SiN). The traditional role for the liners is in the protection of the gate during various processing steps, particularly during etching steps. Such liners typically have selective etching properties. The material of the second liner 21, typically SiO₂, allows oxygen diffusion, affording oxygen to reach the gate dielectric. In the case when the liner material would prevent diffusion of oxygen, for instance, when the liner is made of nitride, the liner is removed prior to the oxygen processing. When oxygen reaches the gate insulator 11, it can shift the threshold voltage of the second type FET by a desired, predetermined amount.

The first type FET device has a first gate insulator 10 and the second type FET device has a second gate insulator 11. Both gate insulators comprise high-k dielectrics. Such high-k dielectrics may be ZrO₂, HfO₂, Al₂O₃, HfSiO, HfSiON, and others, and/or their admixtures. As known in the art, their common property is the possession of a larger dielectric constant than that of the standard oxide (SiO₂) gate insulator material, which has a value of approximately 3.9. In embodiments of the present invention the gate insulator of the first type FET device 10 and the gate insulator of the second type FET device 11 may comprise the same high-k material, or they may have differing high-k materials. In a typical embodiment of the invention the common high-k material present in both gate insulators 10, 11 is HfO₂. Each gate insulator 10, 11, besides the high-k dielectric may have other components, as well. Typically in embodiments of the present invention a very thin, less than about 1 nm, chemically deposited oxide may be present between the high-k dielectric layer and the device body 50. However, any and all inner structure, or the lack of any structure beyond simply containing a high-k dielectric, for either the first or second gate insulators 10, 11, is within the scope of the embodiments of the present invention. In exemplary embodiments of the present invention HfO₂ covering a thin chemical SiO₂ would be used as gate insulator.

The gate 55 of the first type FET device and of the gate 56 of the second type FET device, also referred to as gate stacks, in typical embodiments of the present invention are multilayered structures. They usually include silicon portions 58, 59 in polycrystalline and possibly also in amorphous forms. The top of the gates usually consist of silicide layers 42. In determining the device threshold those portions of the gates 55, 56 are of most significance that are near, or in contact with, the high-k materials of the gate insulators 10, 11.

The first type FET device was processed in such a manner that oxygen was prevented from reaching the gate insulator 10. Accordingly, the threshold of the first type FET device is fixed by the interactions of the gate insulator 10 and the layers in the gate 55 adjacent to the insulator. The gate 55 of the first type FET device contains at least a metal layer 70 and may contain a so called cap layer 80. The metal layer 70 may be selected from a variety of known suitable metals, such as W, Mo, Mn, Ta, Ru, Cr, Ta, Nb, V, Mn, Re, or metallic compounds such as TiN, TaN, WN, and others, and/or their mixtures. The effective work function of the gate may be adjusted by the cap layer 80. Such cap layers are known in art, presented, for instance, by V. Narayanan et al, IEEE VLSI Symposium p. 224, (2006), and by Guha et al. in Appl. Phys. Lett. 90, 092902 (2007). The cap layer 80 may contain materials form Group IIA and/or Group IIIB of the periodic table. In representative embodiments of the invention the cap layer 80 may contain lanthanum (La), which under proper treatment may yield the desired threshold value. In some embodiments of the present invention the high-k material of the gate insulator 10 is in direct contact with the cap layer 80, and the opposite side of the cap layer 80 is in direct contact with the metal layer 70. However, there may be ways to adjust the effective work function of the gate without a cap layer, and such may be used in alternate embodiments of the present invention.

Typical embodiments of the present invention are aiming for high performance circuits, chips, and processors. Accordingly, the FET devices have to be enabled for fast switching, and to conduct large currents. Such aims are served by fabricating devices with low thresholds. For achieving a low threshold for an NFET device it is desirable for the effective workfunction of the gate to be very close to the work function of n-type silicon. And conversely, for achieving a low threshold for a PFET device, it is desirable for the effective workfunction of the gate to be very close to the work function of p-type silicon. With the combination of suitably selected metal 70 and appropriate processing conditions, for instance with the use of cap 80 layers, the threshold of the first type FET device can be adjusted to a wide range of values, including those needed for high performance operation.

In representative embodiments of the present invention the first type FET device would be an NFET, and the effective workfunction of the gate would be like n-type silicon. The saturation threshold voltage would be less than about 0.4 V, with a preferred range of between about 0.1 V and 0.3 V. If the first type FET device were a PFET, the selected saturation threshold voltage would be less negative than −0.4V, with a preferred range of between about −0.1 V and −0.3 V.

The second type FET device usually has no cap layer, and the metal layer 71 of the gate is in direct contact with the high-k material of the gate insulator 11. The final adjustment of the threshold of the second type FET device occurred by exposing the high-k material of the gate insulator 11 to oxygen. In representative embodiments of the present invention the threshold of the second type FET device before the oxygen exposure would correspond to a value which is what one obtains if the gate had an effective workfunction approximately at the middle of the silicon gap. Such a so called midgap workfunction type threshold may result from the use of tungsten (W) as gate metal 71, and HfO₂ for high-k gate dielectric 11. Typically, the second type FET device may be a PFET and the oxygen exposure shifts the threshold of the effective workfunction of the gate to become more like p-type silicon. Those workfunctions which have effective values near those of n⁺ and p⁺ Si, are commonly referred to as band-edge workfunctions. The saturation threshold voltage of the PFET would be a smaller negative value than about −0.4 V, with a preferred range of between about −0.1 V and −0.3 V. If the second type FET device were a NFET, with a different combinations of gate metal 71 and high-k material gate insulator 11, one may have after the oxygen exposure of the high-k material of the gate insulator 11 a saturation threshold voltage of less than about 0.4 V, with a preferred range of between about 0.1 V and 0.3 V.

In some exemplary embodiments of the present invention it is possible that the high-k material of the first gate insulator 10 and the high-k material of the second gate insulator 11 are of the same material, for instance HfO₂. It is also a preferred embodiment to have gate the metals 70, 71 of the first and second type FET device to be the same kind of metals, such as W or TiN.

FIG. 1 further shows the presence of a first dielectric layer 60 overlaying the first gate 55 and at least portions of the vicinity of the first gate. The term vicinity indicates that the first gate is fully, or partially, surrounded, and the vicinity may include the source/drain regions 40, 41 of the first type FET device, and possibly also include isolation structures 99, and the Si based material 50 itself. At the depicted stage of the fabrication there is also a second dielectric layer 61 overlaying the second gate 56 and at least portions of the vicinity of the second gate. The term vicinity indicates that the second gate is fully, or partially, surrounded, and the vicinity may include the source/drain regions 40, 41 of the second type FET device, and possibly also include isolation structures 99, and the Si based material 50 itself.

Both dielectric layers 60, 61 may be in a state of stress, but preferably of opposite sign. If the first dielectric layer 60 is in a compressive state of stress, then the second dielectric layer 61 is preferably in a state of tensile stress. And, conversely, if the first dielectric layer 60 is in a tensile state of stress, then the second dielectric layer 61 is preferably in a state of compressive stress. As one skilled in the art knows, the stress in the dielectric layers 60, 61 imparts a stress into the underlying structures. As known in the art, the state of the stress in the channel regions is the same as in the overlaying dielectric layers. Accordingly, if the first dielectric layer 60 is in a tensile state of stress, then the first channel 44 is also in a tensile state of stress, and if the first dielectric layer 60 is in a compressive state of stress, then the first channel 44 is also in a compressive state of stress. Same relation holds for the second dielectric layer 61 and the second channel 46. Inducing stress of a desirable kind in channel of a FET devices by the use of stressed dielectric layers has been known in the art. See, for instance: “High speed 45nm gate length CMOSFETs integrated into a 90 nm bulk technology incorporating strain engineering” V. Chan et al., IEDM Tech. Dig., pp. 77-80, 2003, and “Dual stress liner for high performance sub-45 nm gate length SOI CMOS manufacturing” Yang, H. S., IEDM Tech. Dig., pp. 1075-1078, 2004.

The properties of charge transport in Si based materials is such that FET performance improves if an NFET channel is under tensile stress, and a PFET channel is under compressive stress. In preferred embodiments of the present invention this pattern is followed, namely using a compressively stressed dielectric layer to cover the PFET and a tensilely stressed dielectric layer to cover the NFET.

In an exemplary embodiments of the present invention both the first 60 and the second 61 dielectric layers are nitride (SiN) layers, which can be deposited as either under compressive, or under tensile stress. The thickness of the stressed nitride layers are usually between about 30 nm and about 80 nm.

It is understood that FIG. 1, as all figures, is only a schematic representation. As known in the art, there may be many more, or less, elements in the structures than presented in the figures, but these would not effect the scope of the embodiments of the present invention.

Further discussions and figures may present only those processing steps which are relevant in yielding the structure of FIG. 1. Manufacturing of NFET, PFET, and CMOS is very well established in the art. It is understood that there are a large number of steps involved in such processing, and each step might have practically endless variations known to those skilled in the art. It is further understood that the whole range of known processing techniques are available for fabricating the disclosed device structures, and only those process steps will be detailed that are related to embodiments of the present invention.

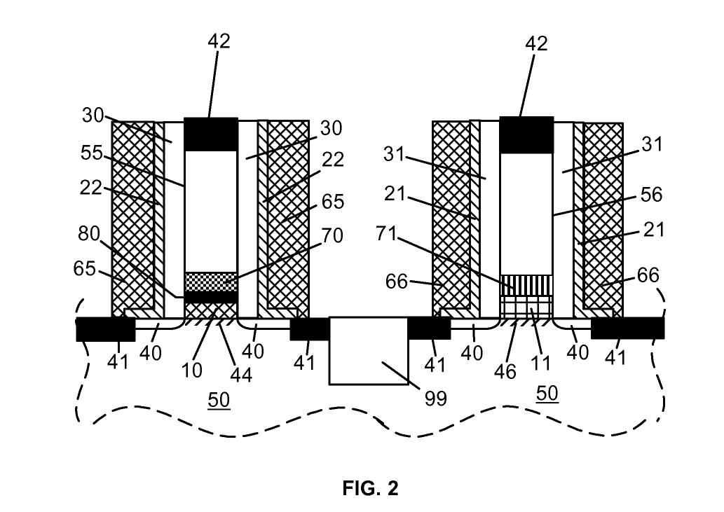

FIG. 2 shows a schematic cross section of a stage in the processing where various layers, including common layers, have been deposited. The first and second type FET devices have reached the depicted stage in the fabrication by the use of processing steps known in the art. The gate insulators 10, 11 comprise the high-k materials, and the gates 55, 56 have the appropriate metal layers. The threshold for the first type FET device has been set, often with the help of a cap layer 80. Spacers 65, 66 are shown as they are elements, as know in the art, for source/drain fabrication and for the silicidation of source/drains 41 and for the silicidation of the gates 42. The spacers 65, 66 typically are made of nitride.

The source/drain 40, 41 of the devices have already been through the high thermal budget activation process. In CMOS processing, typically the largest temperature budgets, meaning temperature and time exposure combinations, are reached during source/drain fabrication. Since the sources and drains have already been fabricated, for the structure of FIG. 2 such high temperature fabrication steps have already been performed, and the structure will not have to be exposed to a further large temperature budget treatment. From the perspective of embodiments of the present invention, exposure to a high temperature budget means a comparable heat treatment as the one used in the source/drain fabrication.

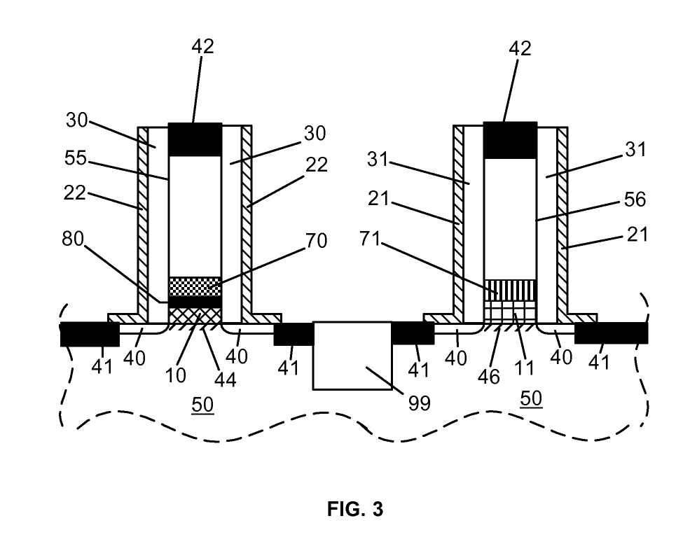

FIG. 3 shows a schematic cross section of a following stage in the processing of an embodiment of the present invention. In standard CMOS fabrication the spacers 65, 66 would remain in place through the many following processing steps. In embodiments of the present invention, however, the final threshold adjustment by oxygen exposure of the second type FET device is yet to be done. The spacer for the second type FET device 66, which is made of nitride, would block oxygen penetration to the high-k material of the gate dielectric 11. Accordingly, the spacer of the second type FET device may have to be removed. The spacer of the first type FET device 65 in principle could stay as a barrier against oxygen penetration. However, embodiments of the present invention call for high performance devices, which preferably are under appropriate stress. In representative embodiments of the present invention the dual roles of protecting the gate dielectric 10 of the first type FET device, and of providing stress for high performance, may be combined into one. Accordingly, usually both spacers 65, 66 are removed. The removal is done by etching in manners known in the art. For instance, hot phosphoric acid, or glycerated buffered hydrofluoric acid, are wet chemistries capable of removing SiN selective to Si. Additionally an isotropic dry etch similar to that of the SiN spacer etch may be used to remove the spacers. These processes etch nitride selectively versus silicon, oxide, and metal, which material may be exposed on the wafer surface while the nitride is being etched.

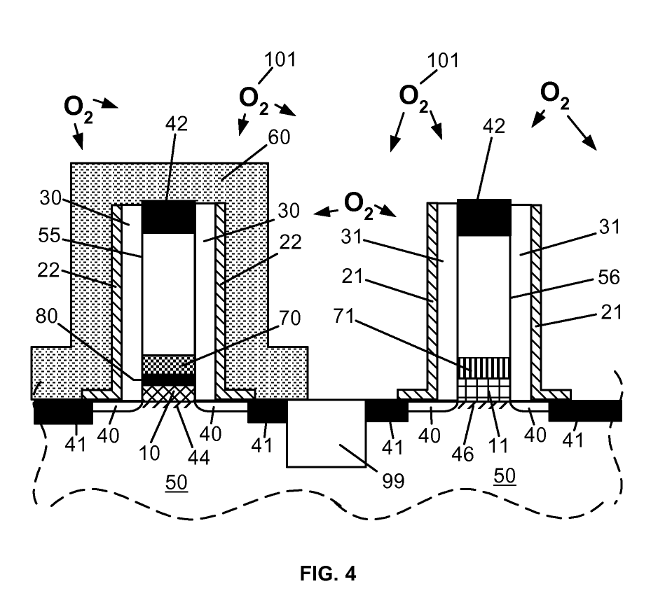

FIG. 4 shows a schematic cross section of a stage in the processing of embodiments of the present invention where a stressed, and oxygen blocking dielectric layer has been deposited, and the structure is exposed to oxygen. After the application of proper blocking masks, as known in the art, the first type FET device is overlaid by a first dielectric layer 60 covering the first gate 55 and at least portions of the vicinity of the first gate. The term vicinity indicates that the first gate is fully, or partially, surrounded, and the vicinity may include the source/drain regions 40, 41 of the first type FET device, and possibly also include isolation structures 99, and the Si based material itself. The first dielectric layer 60 and the first channel 44 are in a first state of stress, which first state of stress is imparted by the first dielectric layer 60 onto the first channel 44. Also, the first dielectric layer 60 is so selected to be a blocker against oxygen penetration. In typical embodiments of the present invention the first dielectric layer 60 is a nitride (SiN) layer. FIG. 4 shows the step of oxygen exposure 101, as well. This exposure may occur at low temperature at about 200° C. to 350° C. by furnace or rapid thermal anneal. The duration of the oxygen exposure 101 may vary broadly from approximately 2 minutes to about 150 minutes. For the duration of the exposure oxygen is blocked by the first dielectric layer 60 from penetrating to the first gate insulator 10, but oxygen is capable of penetrating to the second gate insulator 11. The amount of threshold shift for the second type FET device depends on the oxygen exposure parameters, primarily on the duration and the temperature of the procedure. In exemplary embodiments of the present invention the size of the threshold shift is so selected that the final threshold is suited for high performance applications, wherein typically the saturation threshold is in absolute value less than about 0.4 V.

After the oxygen exposure step, the second type FET device may be overlaid with a second dielectric layer 61, in a second state of stress, which is imparted to the second channel 46. The second state of stress of the second dielectric layer 61 preferably has a sign opposite to that of the first state of stress of the first dielectric layer 60. In exemplary embodiments of the present invention the second dielectric layer 61 is a nitride (SiN) layer. Stressed dielectric layers and their implementation by SiN is discussed in more detail in U.S. patent application Ser. No. 11/682,554, filed on Mar. 6, 2007, titled: “Enhanced Transistor Performance by Non-Conformal Stressed Layers”, incorporated herein by reference. With the second dielectric layer 61 in place, one arrives to the structure as displayed in FIG. 1, and discussed relating to FIG. 1.

The CMOS structure, and its wiring into circuits, may be completed with standard steps known to one skilled in the art.

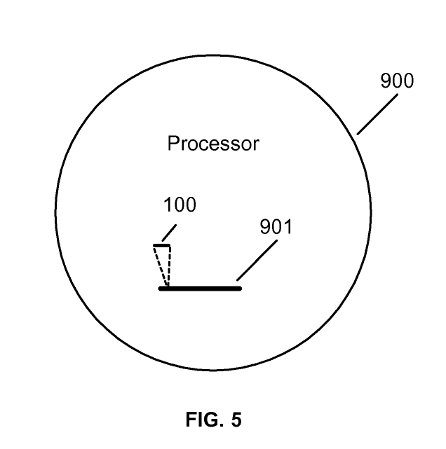

FIG. 5 shows a symbolic view of a processor containing at least one CMOS circuit according to an embodiment of the present invention. Such a processor 900 has at least one chip 901, which contains at least one CMOS structure 100, with at least one NFET and one PFET having high-k gate dielectrics, gates comprising metals, and possibly a cap layer in one of the gates, and stressed dielectric layers covering the NMOS and CMOS devices, as described relating to FIGS. 1-4. The saturation thresholds of the FETs are optimized for high performance. The processor 900 may be any processor which can benefit from embodiments of the present invention, which yields high performance circuits. Representative embodiments of processors manufactured with embodiments of the disclosed structure are digital processors, typically found in the central processing complex of computers; mixed digital/analog processors, typically found in communication equipment; and others.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

We claim:

1. A CMOS structure, comprising:
at least one first type FET device, said first type FET comprises:
a first channel hosted in a Si based material;
a first gate comprising a first metal;
a first gate insulator comprising a first high-k dielectric;
a first dielectric layer overlaying said first gate and at least portions of said first gate's vicinity, wherein said first dielectric layer and said first channel are in a first state of stress, wherein said first state of stress is imparted by said first dielectric layer onto said first channel;
at least one second type FET device, said second type FET comprises:
a second channel hosted in said Si based material;
a second gate comprising a second metal;
a second gate insulator comprising a second high-k dielectric, wherein said second high-k dielectric is in direct contact with said second metal;
a second dielectric layer overlaying said second gate and at least portions of said second gate's vicinity, wherein said second dielectric layer and said second channel are in a second state of stress, wherein said second state of stress is imparted by said second dielectric layer onto said second channel; and
wherein absolute values of the saturation thresholds of said first and said second FET devices are less than about 0.4 V.

2. The CMOS structure of claim 1, wherein said first type FET device is a PFET device, and said second type FET device is an NFET device.

3. The CMOS structure of claim 1, wherein said first type FET device is an NFET device, and said second type FET device is a PFET device.

4. The CMOS structure of claim 1, wherein said first state of stress is compressive stress, and said second state of stress is tensile stress.

5. The CMOS structure of claim 1, wherein said first state of stress is tensile stress, and said second state of stress is compressive stress.

6. The CMOS structure of claim 1, wherein said first high-k dielectric and said second high-k dielectric are of a same material.

7. The CMOS structure of claim 1, wherein said first high-k dielectric and said second high-k dielectric are both composed of HfO₂.

8. The CMOS structure of claim 1, wherein said first dielectric layer and said second dielectric layer are both composed of SiN.

9. The CMOS structure of claim 1, wherein said first gate further comprises a cap layer, and wherein said first high-k dielectric is in direct contact with said cap layer.

10. The CMOS structure of claim 1, wherein said absolute values of the saturation thresholds of said first and said second FET devices are between about 0.1 V and 0.3 V.

11. A method for processing a CMOS structure, comprising:
in a first type FET device, implementing a first gate insulator comprising a first high-k dielectric, wherein a first channel underlies said first gate insulator, wherein said first channel is in a Si based material, further implementing a first gate comprising a first metal;
overlaying said first gate and at least portions of said first gate's vicinity with a first dielectric layer, wherein said first dielectric layer is in a first state of stress and said first dielectric layer imparts said first state of stress onto said first channel;
in a second type FET device, implementing a second gate insulator comprising a second high-k dielectric, wherein a second channel underlies said second gate insulator, wherein said second channel is in said Si based material, further implementing a second gate comprising a second metal, wherein said second high-k dielectric is in direct contact with said second metal; and
exposing said first type FET device and said second type FET device to oxygen, wherein oxygen reaches said second high-k dielectric of said second gate insulator, and adjusts the saturation threshold voltage of said second type FET device to be less than about 0.4 V in an absolute value, while due to said first dielectric layer oxygen is prevented from reaching said first high-k dielectric of said first gate insulator, whereby the threshold voltage of said first type FET device stays unchanged.

12. The method of claim 11, wherein said first type FET device is selected to be a PFET device, and said second type FET device is selected to be an NFET device.

13. The method of claim 1 1, wherein said first type FET device is selected to be an NFET device, and said second type FET device is selected to be a PFET device.

14. The method of claim 11, wherein said first high-k dielectric and said second high-k dielectric are selected to be of a same material.

15. The method of claim 11, wherein said first high-k dielectric and said second high-k dielectric are both selected to be HfO₂.

16. The method of claim 11, further comprising:
implementing said first gate to comprise a cap layer, and forming said cap layer in such manner that said first high-k dielectric is in direct contact with said cap layer.

17. The method of claim 11, further comprising:
overlaying said second gate at least portions of said second gate's vicinity with a second dielectric layer, wherein said second dielectric layer is in a second state of stress and said second dielectric layer imparts said second state of stress onto said second channel.

18. The method of claim 17, wherein said first dielectric layer and said second dielectric layer are both selected to be SiN.

19. The method of claim 17, wherein said first state of stress is selected to be compressive, and said second state of stress is selected to be tensile.

20. The method of claim 17, wherein said first state of stress is selected to be tensile, and said second state of stress is selected to be compressive.

21. The method of claim 11, further comprising:
adjusting absolute values of the saturation thresholds of said first and said second FET devices to be between about 0.1 V and about 0.3 V.

22. A processor comprising at least one CMOS circuit, said CMOS further comprising:
at least one first type FET device, said first type FET comprises:
a first channel hosted in a Si based material;
a first gate comprising a first metal;
a first gate insulator comprising a first high-k dielectric;
a first dielectric layer overlaying said first gate and at least portions of said first gate's vicinity, wherein said first dielectric layer and said first channel are in a first state of stress, wherein said first state of stress is imparted by said first dielectric layer onto said first channel;
at least one second type FET device, said second type FET comprises:
a second channel hosted in said Si based material;
a second gate comprising a second metal;
a second gate insulator comprising a second high-k dielectric, wherein said second high-k dielectric is in direct contact with said second metal;
a second dielectric layer overlaying said second gate and at least portions of said second gate's vicinity, wherein said second dielectric layer and said second channel are in a second state of stress, wherein said second state of stress is imparted by said second dielectric layer onto said second channel; and
wherein absolute values of the saturation thresholds of said first and said second FET devices are less than about 0.4 V.
